(19) United States
(12) Patent Application Publication
(10) Pub. No.: US 2012/0298967 A1
(43) Pub. Date: Nov. 29, 2012

(54) ORGANIC LIGHT EMITTING DEVICE

(75) Inventors: Ting-Yi Cho, New Taipei City (TW); Chieh-Wei Chen, Taichung City (TW)

(73) Assignee: AU OPTRONICS CORPORATION, Hsinchu (TW)

(21) Appl. No.: 13/210,388

(22) Filed: Aug. 16, 2011

(30) Foreign Application Priority Data
May 24, 2011 (TW) 100118142

(51) Int. Cl. H01L 51/54

(52) U.S. Cl. 257/40; 257/E51.018; 257/E51.026

(57) ABSTRACT

An organic light emitting device is provided and suitable for being disposed on a substrate. The organic light emitting device includes a cathode layer, a buffer layer, a material layer, an organic light emitting layer and an anode layer. The cathode layer is disposed on the substrate. The buffer layer is disposed on and contacts the cathode layer, and the cathode layer is disposed between the substrate and the buffer layer. The material layer is disposed on and contacts the buffer layer, and the buffer layer is disposed between the cathode layer and the material layer, wherein a difference between a lowest unoccupied molecular orbital of the buffer layer and a highest occupied molecular orbital of the material layer is smaller than 2 eV. The organic light emitting layer is disposed on the material layer. The anode layer is disposed on the organic light emitting layer.

### CROSS-REFERENCE TO RELATED APPLICATION

This application claims the priority benefit of Taiwan application serial no. 100118142, filed May 24, 2011. The entirety of the above-mentioned patent application is hereby incorporated by reference herein and made a part of this specification.

### BACKGROUND OF THE INVENTION

1. Field of the Invention

The invention relates to an organic light emitting device, and particularly to an inverted organic light emitting device.

2. Description of Related Art

Recently, a flat panel display has been the focus display as the technology is advanced. In particular, an organic electro-luminescence display has the advantages of self-luminescence, no viewing angle restriction, low power consumption, simple manufacturing process, low production cost, low operation temperature, fast responsive speed and full-colors. Accordingly, the organic electro-luminescence display has great potential for applications and becomes the mainstream for the next generation displays. The organic light emitting device (OLED) is typically comprised of a pair of electrodes and the organic functional layer. As the current passes through the area between the transparent anode and the metallic cathode, the electrons and the holes are combined in the organic light emitting layer to produce excitons, thus allowing the organic light emitting layer, according to its material characteristics, to produce different light emitting mechanisms for different colors.

The inverted OLED generally includes a cathode layer, an electron transporting layer, an organic light emitting layer and an anode layer which are sequentially disposed on the substrate. The inverted OLED is suitable for being connected to the drain of the n-type transistor, so that the inverted OLED can have stable electrical performance as being driven. However, in the inverted OLED, the electron transporting layer is fabricated on the lower electrode, and the lower electrode is usually formed by relatively stable conductive material and has higher work function. Accordingly, the cathode layer has higher energy barrier for electron injection, and thus phenomena of breakdown or instability is occurred in the electrode interface. Moreover, as the electron injection is limited to higher energy barrier, the number of the injected electrons and the number of the injected holes are unbalanced, and thus the effective combination between the electrons and the holes can not be achieved. Accordingly, the luminous efficiency and the lifetime of the OLED are reduced.

### SUMMARY OF THE INVENTION

The invention provides an organic light emitting device which has better luminous efficiency and stability.

The invention provides an organic light emitting device which is suitable for being disposed on a substrate. The organic light emitting device includes a cathode layer, a buffer layer, a material layer, an organic light emitting layer and an anode layer. The cathode layer is disposed on the substrate. The buffer layer is disposed on and contacts the cathode layer, wherein the cathode layer is disposed between the substrate and the buffer layer. The material layer is disposed on and contacts the buffer layer, wherein the buffer layer is disposed between the cathode layer and the material layer, and a difference between a lowest unoccupied molecular orbital (LUMO) of the buffer layer and a highest occupied molecular orbital (HOMO) of the material layer is smaller than 2 eV. The organic light emitting layer is disposed on the material layer. The anode layer is disposed on the organic light emitting layer.

Based on the above, the organic light emitting device of the invention includes the buffer layer disposed between the cathode layer and the material layer, and the difference between the LUMO of the buffer layer and the HOMO of the material layer is smaller than 2 eV. Therefore, the energy barrier between the cathode layer and the material layer for electron injection is reduced, and the luminous efficiency and the operation stability are greatly increased.

In order to make the aforementioned and other features and advantages of the invention more comprehensible, embodiments accompanying figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1 is schematic cross-sectional view illustrating an organic light emitting device according to a first embodiment of the invention.

FIG. 2 is schematic cross-sectional view illustrating an organic light emitting device according to a second embodiment of the invention.

FIG. 3 show the relationship between brightness and time of the organic light emitting devices according to the experimental and comparative examples, wherein the initial brightness is 4000 nits and the organic light emitting devices are driven by a direct current.

### DESCRIPTION OF EMBODIMENTS

### The First Embodiment

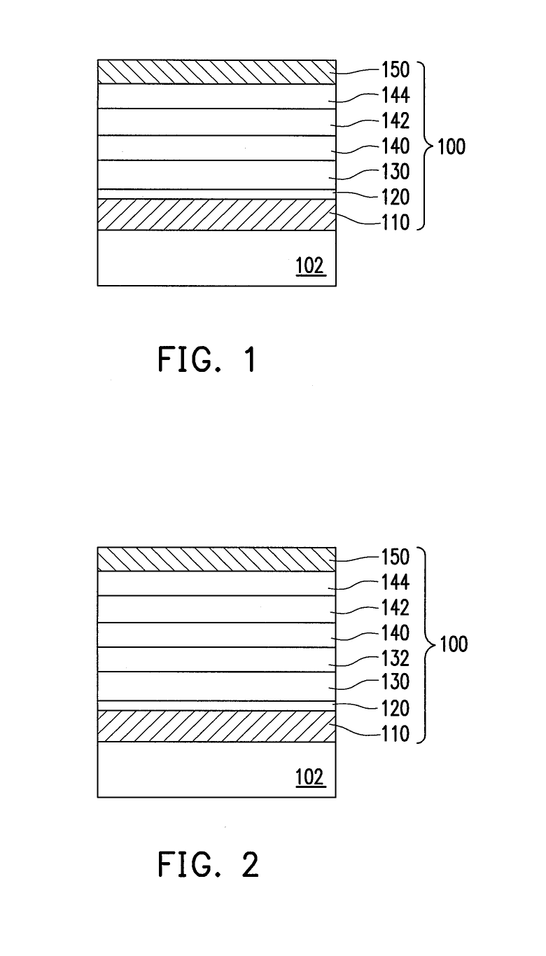

FIG. 1 is schematic cross-sectional view illustrating an organic light emitting device according to the first embodiment of the invention. Referring to FIG. 1, an organic light emitting device 100 is suitable for being disposed on a substrate 102. The organic light emitting device 100 includes a cathode layer 110, a buffer layer 120, a material layer 130, an organic light emitting layer 140 and an anode layer 150. The organic light emitting device 100 is, for example, an inverted organic light emitting device. According to the present embodiment, the organic light emitting device 100 is suitable for connecting with the drain of the n-type transistor in the driver circuit system of the display, for example.

The cathode layer 110 is disposed on the substrate 102. The substrate 102 can be made of glass, quartz, an organic polymer, plastic, flexible plastic, light-shielding materials, or reflective materials, and is not limited by the present invention. The cathode layer 110 can have a single-layered or multiple-layered structure, and the material thereof can be a transparent conductive material or a non-transparent conductive material. The transparent conductive material includes metal oxide, such as indium tin oxide (ITO), indium zinc oxide (IZO), aluminum tin oxide (ATO), aluminum zinc oxide (AZO), indium germanium zinc oxide, other suitable oxide such as zinc oxide, or a stacked layer having at least two of the above materials. The non-transparent conductive material is, for example, metals such as silver, aluminum, molybdenum, copper, or titanium, or other suitable conductive materials.

The buffer layer 120 is disposed on and contacts the cathode layer 110, wherein the cathode layer 110 is disposed between the substrate 102 and the buffer layer 120. The material layer 130 is disposed on the buffer layer 120 and contacts the buffer layer 120. In detail, the buffer layer 120 is disposed between the cathode layer 110 and the material layer 130, and contacts the cathode layer 110 and the material layer 130, respectively. The difference between the lowest unoccupied molecular orbital (LUMO) of the buffer layer 120 and the highest occupied molecular orbital (HOMO) of the material layer 130 is smaller than 2 eV. In this embodiment, the material layer 130 is an electron transporting layer, for example. A method of forming the material layer 130 is, for example, evaporation, and a thickness thereof is, for example, 10 nm. A material of the buffer layer 120 can be an organic material, and the LUMO of the organic material is, for example, smaller than −4.0 eV. Meanwhile, the HOMO of the material layer 130 is preferably larger than −8.0 eV. According to the present embodiment, a material of the buffer layer 120 includes, for example, HAT-CN and has the following structure, and the LUMO of HAT-CN is about −6.0 eV.

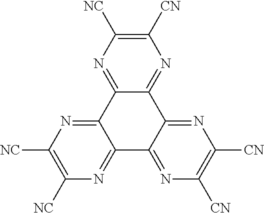

The material layer 130 includes, for example, tris(8-quinolinato-N1,08)-aluminum (Alq), aluminum(III)bis-(2-methyl-8-quinolinato)-4-phenylphenolate (BAlq), bathophenanthroline (BCP), 4,7-diphenyl-1,10-phenanthroline (Bphen), 4,4′-di(9-carbazolyl)biphenyl (CBP), 3-(4-biphenyl)-4-phenyl-5-(4-tert-butylphenyl)-1,2,4-triazole (TAZ), or other organic materials which have electron transporting properties and a HOMO larger than −8.0 eV.

In another embodiment, the material of the buffer layer 120 is, for example, 1,4,5,8-Naphthalenetetracarboxylic dianhydride (NTCDA) and the LUMO of NTCDA is about −4.7 eV, and the HOMO of the material layer 130 is, for example, larger than −5.7 eV and includes materials such as tris(8-quinolinato-N1,08)-aluminum (Alq), aluminum(III)bis-(2-methyl-8-quinolinato)-4-phenylphenolate (BAlq) or other organic materials which have electron transporting properties and a HOMO larger than −5.7 eV. In still another embodiment, the material of the buffer layer 120 is, for example, tetrafluoro-tetracyano-quinodimethane (F₄-TCNQ) and the LUMO of F₄-TCNQ is about −5.3 eV, and the HOMO of the material layer 130 is, for example, larger than −7.3 eV and includes materials such as tris(8-quinolinato-N1,08)-aluminum (Alq), aluminum(III)bis-(2-methyl-8-quinolinato)-4-phenylphenolate (BAlq), bathophenanthroline (BCP), 4,7-diphenyl-1,10-phenanthroline (Bphen), 4,4′-di(9-carbazolyl)biphenyl (CBP), or other organic materials which have electron transporting properties and a HOMO larger than −7.3 eV.

The organic light emitting layer 140 is disposed on the material layer 130. The organic light emitting layer 140 can include, for example, a red organic light emitting pattern, a green organic light emitting pattern, a blue organic light emitting pattern, or a combination of the aforementioned.

The anode layer 150 is disposed on the organic light emitting layer 140. According to the present embodiment, the materials of the anode layer 150 can refer to those of the cathode layer 110 mentioned above or any other suitable materials, and thus further descriptions are omitted. According to the present embodiment, the organic light emitting device 100 further includes a hole transporting layer 142 and a hole injecting layer 144, wherein the hole transporting layer 142 and the hole injecting layer 144 are, for example, sequentially stacked on the organic light emitting layer 140 and disposed between the anode layer 150 and the organic light emitting layer 140. In detail, the hole transporting layer 142 is, for example, disposed between the hole injecting layer 144 and the organic light emitting layer 140. The hole injecting layer 144 is, for example, disposed between hole transporting layer 142 and the anode layer 150. Certainly, in other embodiments, the disposition of the hole transporting layer 142 and the hole injecting layer 144 is optional. In other words, according to an embodiment, the organic light emitting device 100 may not include the hole transporting layer 142 and the hole injecting layer 144, or only one of the hole transporting layer 142 and the hole injecting layer 144 is disposed in the organic light emitting device 100.

According to the present embodiment, the buffer layer 120 is disposed between the cathode layer 110 and the material layer 130 which is served as an electron transporting layer, and the difference between the LUMO of the buffer layer 120 and the HOMO of the material layer 130 is smaller than 2 eV. Thus, the energy barrier for electron injection, at the interface of the cathode layer, is efficiently reduced, so as to increase the stability of the interface of the cathode layer. Accordingly, the number of the injected electrons and the number of the injected holes are balanced, and thus the effective combination between the electrons and the holes can be achieved. Therefore, the luminous efficiency, the operation stability, and the lifetime of the organic light emitting device 100 are greatly increased.

### The Second Embodiment

FIG. 2 is schematic cross-sectional view illustrating an organic light emitting device according to the second embodiment of the invention. Referring to FIG. 2, an organic light emitting device 100 is suitable for being disposed on a substrate 102. The organic light emitting device 100 includes a cathode layer 110, a buffer layer 120, a material layer 130, an electron transporting layer 132, an organic light emitting layer 140 and an anode layer 150.

The cathode layer 110 is disposed on the substrate 102. The buffer layer 120 is disposed on the cathode layer 110 and contacts the cathode layer 110. According to the present embodiment, the cathode layer 110 is disposed between the substrate 102 and the buffer layer 120, that is, the organic light emitting device 100 is an inverted organic light emitting device. The material layer 130 is disposed on the buffer layer 120 and contacts the buffer layer 120. The difference between the lowest unoccupied molecular orbital (LUMO) of the buffer layer 120 and the highest occupied molecular orbital (HOMO) of the material layer 130 is smaller than 2 eV. In this embodiment, the material layer 130 is an electron injecting layer, and a material thereof includes, for example, inorganic materials or organic materials doped with conductive dopants such as inorganic materials or organic materials doped with alkaline metals or alkaline earth metals. According to the present embodiment, the LUMO of the buffer layer 120 is smaller than −4.0 eV, and the HOMO of the material layer 130 is larger than −8.0 eV. According to the present embodiment, a material of the buffer layer 120 includes, for example, HAT-CN, and the HOMO of the material layer 130 is, for example, larger than −8.0 eV. The material layer 130 can includes tris(8-quinolinato-N1,08)-aluminum (Alq), aluminum(III)bis-(2-methyl-8-quinolinato)-4-phenylphenolate (BAlq), bathophenanthroline (BCP), 4,7-diphenyl-1,10-phenanthroline (Bphen), 4,4′-di(9-carbazolyl)biphenyl (CBP), or 3-(4-biphenyl)-4-phenyl-5-(4-tert-butylphenyl)-1,2,4-triazole (TAZ) which is selectively doped with alkaline metals or alkaline earth metals such as Li, Na, K, Ru, Cs, Mg, Ca, Sr, or Ba, or other organic materials which have electron transporting properties and a HOMO larger than −8.0 eV.

According to another embodiment, the material of the buffer layer 120 includes, for example, 1,4,5,8-Naphthalenetetracarboxylic dianhydride. The HOMO of the material layer 130 is, for example, larger than −5.7 eV, and includes, for example, tris(8-quinolinato-N1,08)-aluminum (Alq) or aluminum(III)bis-(2-methyl-8-quinolinato)-4-phenylphenolate (BAlq) which is selectively doped with alkaline metals or alkaline earth metals such as Li, Na, K, Ru, Cs, Mg, Ca, Sr, or Ba, or other organic materials which have electron transporting properties and a HOMO larger than −5.7 eV. According to still another embodiment, the material of the buffer layer 120 includes, for example, tetrafluoro-tetracyano-quinodimethane (F₄-TCNQ). The HOMO of the material layer 130 is, for example, larger than −7.3 eV, and includes, for example, tris(8-quinolinato-N1,08)-aluminum (Alq), aluminum(III)bis-(2-methyl-8-quinolinato)-4-phenylphenolate (BAlq), bathophenanthroline (BCP), 4,7-diphenyl-1,10-phenanthroline (Bphen), 4,4′-di(9-carbazolyl)biphenyl (CBP) which is selectively doped with alkaline metals or alkaline earth metals such as Li, Na, K, Ru, Cs, Mg, Ca, Sr, or Ba, or other organic materials which have electron transporting properties and a HOMO larger than −7.3 eV. It is mentioned that, although the material layer 130 described in the above embodiments includes organic materials, but the invention is not limited thereto. According to other embodiments, the material layer 130 can include inorganic materials which are selectively doped with alkaline metals or alkaline earth metals such as Li, Na, K, Ru, Cs, Mg, Ca, Sr, or Ba. In other word, the materials of the buffer layer 120 and the material layer 130 are not limited as long as the difference between the lowest unoccupied molecular orbital (LUMO) of the buffer layer 120 and the highest occupied molecular orbital (HOMO) of the material layer 130 is smaller than 2 eV.

The electron transporting layer 132 is disposed between the material layer 130 served as the electron injecting layer and the organic light emitting layer 140. According to the present embodiment, the material of the electron transporting layer 132 can be substantially the same as that of the material layer 130 and are undoped materials, or the material of the electron transporting layer 132 can be other materials well known to people having ordinary skill in the pertinent art, and the invention is not limited thereto.

The organic light emitting layer 140 is disposed on the electron transporting layer 132. The anode layer 150 is disposed on the organic light emitting layer 140. The materials of the cathode layer 110, the organic light emitting layer 140 and the anode layer may refer to the first embodiment for descriptions related to the above, and thus further descriptions are omitted. According to the present embodiment, the organic light emitting device 100 further includes a hole transporting layer 142 and a hole injecting layer 144, wherein the hole transporting layer 142 is, for example, disposed between the hole injecting layer 144 and the organic light emitting layer 140, and the hole injecting layer 144 is, for example, disposed between hole transporting layer 142 and the anode layer 150. Certainly, in other embodiments, the disposition of the hole transporting layer 142 and the hole injecting layer 144 is optional, and the invention is not limited thereto.

According to the present embodiment, the buffer layer 120 is disposed between the cathode layer 110 and the material layer 130 which is served as an electron injecting layer, and the difference between the LUMO of the buffer layer 120 and the HOMO of the material layer 130 is smaller than 2 eV. Thus, the energy barrier for electron injection, at the interface of the cathode layer, is efficiently reduced, so as to increase the stability of the interface of the cathode layer. Accordingly, the number of the injected electrons and the number of the injected holes are balanced, and thus the effective combination between the electrons and the holes can be achieved. Therefore, the luminous efficiency, the operation stability, and the lifetime of the organic light emitting device 100 are greatly increased.

The following describes an experimental example to verify the effects described by the invention.

### Experimental Example

In order to verify that the organic light emitting device according to the above embodiments has better device characteristics, an experimental example is compared with a comparative example. The organic light emitting device according to the experimental example has a structure as shown in FIG. 1, wherein the cathode layer includes indium tin oxide and has a work function value of 5.0 eV, the buffer layer includes F₄-TCNQ and has a LUMO of −5.3 eV and a thickness of 10 nm, the electron transporting layer includes Li-doped tris(8-quinolinato-N1,08)-aluminum (Alq:Li), the organic light emitting layer includes mCP:Ir(ppy)₃, the hole transporting layer includes TCTA, the hole injecting layer includes m-MTDATA:F₄-TCNQ, and the anode layer includes aluminum. The organic light emitting device according to the comparative example has a structure similar to that of the organic light emitting device according to the experimental example, and the difference lies in the organic light emitting device according to the comparative example doesn't have a buffer layer, that is, other layers of the organic light emitting devices according to the experimental and comparative examples are the same. The organic light emitting devices according to the experimental and comparative examples are tested for operation stability when the initial brightness is 4000 nits and the organic light emitting devices are driven by a direct current. In the test, operation stability of the organic light emitting device is determined according to the lifetime (LT50) of the organic light emitting device.

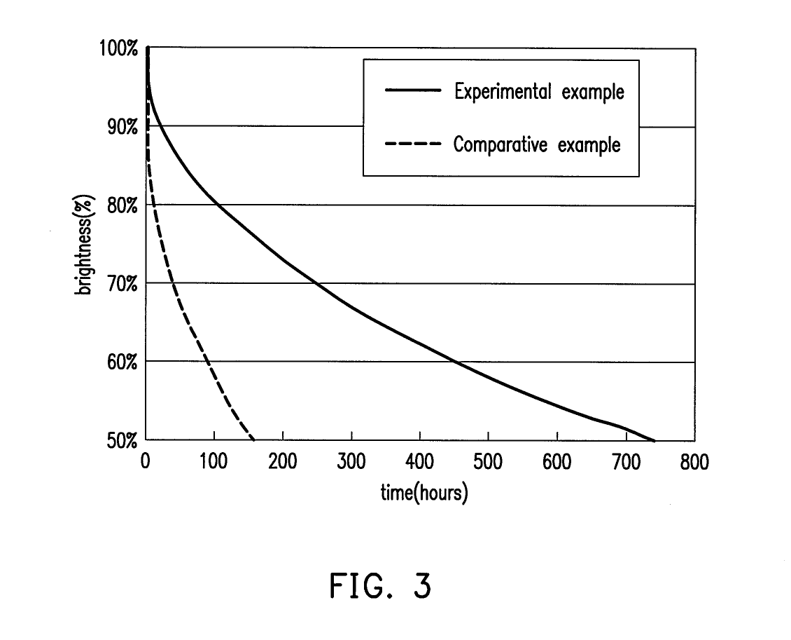

FIG. 3 show the relationship between brightness and time of the organic light emitting devices according to the experimental and comparative examples, wherein the initial brightness is 4000 nits and the organic light emitting devices are driven by a direct current. According to FIG. 3, the lifetime of the organic light emitting device according to the experimental example is about 730 hours, and the lifetime of the organic light emitting device according to the comparative example is about 150 hours. In other words, the lifetime of the organic light emitting device according to the experimental example is about 4.8 times the lifetime of the organic light emitting device according to the comparative example. Therefore, based on the above results, it is known that, in the organic light emitting device, the disposition of the buffer layer contacting the cathode layer improves the lifetime of the organic light emitting device, so as to increase the operation stability of the organic light emitting device.

In light of the foregoing, the organic light emitting device of the invention includes the buffer layer disposed between the cathode layer and the material layer, and the difference between the LUMO of the buffer layer and the HOMO of the material layer is smaller than 2 eV. The material layer can be served as an electron transporting layer or an electron injecting layer, and thus the buffer layer is, for example, disposed between the cathode layer and the electron transporting layer or the cathode layer and the electron injecting layer. Therefore, the energy barrier for electron injection, at the interface of the cathode layer, is efficiently reduced, so as to increase the stability of the interface of the cathode layer. Accordingly, the number of the injected electrons and the number of the injected holes are balanced, and thus the effective combination between the electrons and the holes can be achieved. Therefore, the luminous efficiency, the operation stability, and the lifetime of the organic light emitting device 100 are greatly increased.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. An organic light emitting device, suitable for being disposed on a substrate, comprising:
a cathode layer, disposed on the substrate;
a buffer layer, disposed on and contacting the cathode layer, wherein the cathode layer is disposed between the substrate and the buffer layer;
a material layer, disposed on and contacting the buffer layer, wherein the buffer layer is disposed between the cathode layer and the material layer, and a difference between a lowest unoccupied molecular orbital (LUMO) of the buffer layer and a highest occupied molecular orbital (HOMO) of the material layer is smaller than 2 eV;
an organic light emitting layer, disposed on the material layer; and
an anode layer, disposed on the organic light emitting layer.

2. The organic light emitting device as claimed in claim 1, wherein the material layer is an electron transporting layer.

3. The organic light emitting device as claimed in claim 1, wherein the material layer is an electron injecting layer.

4. The organic light emitting device as claimed in claim 3, further comprising an electron transporting layer disposed between the material layer and the organic light emitting layer.

5. The organic light emitting device as claimed in claim 1, wherein the buffer layer comprises an organic material.

6. The organic light emitting device as claimed in claim 5, wherein the LUMO of the organic material is smaller than −4.0 eV.

7. The organic light emitting device as claimed in claim 1, wherein the HOMO of the material layer is larger than −8.0 eV.

8. The organic light emitting device as claimed in claim 7, wherein the buffer layer comprises HAT-CN shown as below:

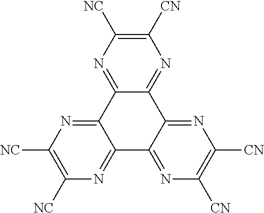

9. The organic light emitting device as claimed in claim 7, wherein the material layer comprises tris(8-quinolinato-N1,08)-aluminum (Alq), aluminum(III)bis-(2-methyl-8-quinolinato)-4-phenylphenolate (BAlq), bathophenanthroline (BCP), 4,7-diphenyl-1,10-phenanthroline (Bphen), 4,4′-di(9-carbazolyl)biphenyl (CBP) or 3-(4-biphenyl)-4-phenyl-5-(4-tert-butylphenyl)-1,2,4-triazole (TAZ).

10. The organic light emitting device as claimed in claim 1, wherein the HOMO of the material layer is larger than −5.7 eV.

11. The organic light emitting device as claimed in claim 10, wherein the buffer layer comprises 1,4,5,8-Naphthalenetetracarboxylic dianhydride.

12. The organic light emitting device as claimed in claim 10, wherein the material layer comprises tris(8-quinolinato-N1,08)-aluminum (Alq) or aluminum(III)bis-(2-methyl-8-quinolinato)-4-phenylphenolate (BAlq).

13. The organic light emitting device as claimed in claim 1, wherein the HOMO of the material layer is larger than −7.3 eV.

14. The organic light emitting device as claimed in claim 13, wherein the buffer layer comprises tetrafluoro-tetracyano-quinodimethane (F₄-TCNQ).

15. The organic light emitting device as claimed in claim 13, wherein the material layer comprises tris(8-quinolinato-N1,08)-aluminum (Alq), aluminum(III)bis-(2-methyl-8-quinolinato)-4-phenylphenolate (BAlq), bathophenanthroline (BCP), 4,7-diphenyl-1,10-phenanthroline (Bphen) or 4,4′-di(9-carbazolyl)biphenyl (CBP).

16. The organic light emitting device as claimed in claim 1, further comprising a hole injecting layer disposed between the anode layer and the organic light emitting layer.

17. The organic light emitting device as claimed in claim 1, further comprising a hole transporting layer disposed between the anode layer and the organic light emitting layer.

18. The organic light emitting device as claimed in claim 1, wherein a material of the cathode layer comprises indium tin oxide (ITO), zinc oxide, silver, aluminum, molybdenum, copper or titanium.
